(19) United States
(12) Patent Application Publication
(10) Pub. No.: US 2026/0282676 A1
(43) Pub. Date: Sep. 17, 2026

(54) DISPLAY DEVICE

(71) Applicant: LG Display Co., Ltd., Seoul (KR)

(72) Inventors: Heeyoung CHAE, Paju-si (KR); Jongsin PARK, Paju-si (KR)

(21) Appl. No.: 19/394,842

(22) Filed: Nov. 19, 2025

(30) Foreign Application Priority Data
Mar. 11, 2025 (KR) 10-2025-0031544

(51) Int. Cl. H10K 59/131; H10K 59/38

(52) U.S. Cl. CPC H10K 59/131; H10K 59/38

(57) ABSTRACT

A display device including a substrate having a display area including a plurality of pixels and a non-display area surrounding the display area, a first high voltage line surrounding the display area in the non-display area on the substrate, and a second high voltage line whose one end and the other end are each electrically connected to the first high voltage line and which is electrically connected to a first pixel row including the pixels disposed in a first direction. Both ends of the second high voltage line are electrically connected to the first high voltage line in the non-display area.

### CROSS REFERENCE TO RELATED APPLICATION

This application claims priority from and the benefit of Korean Patent Application No. 10-2025-0031544, filed on Mar. 11, 2025, which is hereby incorporated by reference for all purposes as if fully set forth herein.

### BACKGROUND

### Field

Embodiments of the invention relate generally to a display device having an improved aperture ratio, improved wiring design, and low power consumption.

### Discussion of the Background

As the information society develops, various demands for display devices for displaying images are increasing, and various types of display devices such as liquid crystal display (LCD) devices and organic light emitting diode (OLED) display devices are utilized. A display device includes a plurality of pixels and a plurality of switching elements for driving and controlling the pixels, and there has been a continuing need in the field for improvements in aperture ratio and wiring design, along with lower power consumption.

The above information disclosed in this Background section is only for understanding of the background of the inventive concepts, and, therefore, it may contain information that does not constitute prior art.

### SUMMARY

Display devices according to embodiments of the invention are capable of providing an improved aperture ratio and ease of wiring design, along with lower power consumption.

Additional features of the inventive concepts will be set forth in the description which follows, and in part will be apparent from the description, or may be learned by practice of the inventive concepts.

According to one or more embodiments of the invention, a display device includes a substrate including a display area including a plurality of pixels and a non-display area surrounding the display area; a first high voltage line surrounding the display area in the non-display area on the substrate; and a second high voltage line having both ends electrically connected to the first high voltage line and which is electrically connected to a first pixel row including the pixels disposed in a first direction. Both ends of the second high voltage line are electrically connected to the first high voltage line in the non-display area.

The display device may further include a scan line electrically connected to the first pixel row and a data line electrically connected to a first pixel column including pixels disposed along a second direction intersecting the first direction. The second high voltage line, the scan line, and the data line may be disposed in different layers.

The display device may further include a first conductive layer on the substrate; a second conductive layer on the first conductive layer; and a third conductive layer on the second conductive layer.

The data line may be disposed in the first conductive layer, the second high voltage line may be disposed in the third conductive layer, and the scan line may be disposed in the second conductive layer.

The data line may be disposed in the first conductive layer, the second high voltage line may be disposed in the second conductive layer, and the scan line may be disposed in the third conductive layer.

The display device may further include a color filter on the third conductive layer, and a planarization layer on the color filter.

The pixel may include a plurality of sub-pixels, and color filters disposed on the adjacent sub-pixels may overlap each other at boundaries between the adjacent sub-pixels.

The display device may further include an anode electrode disposed on the third conductive layer.

The pixel may include a light-emitting area and a non-light-emitting area surrounding the light-emitting area. The anode electrode may overlap the entire light-emitting area, and a portion of the anode electrode may overlap the non-light-emitting area.

The anode electrode and the second high voltage line may be electrically connected.

The anode electrode and the second high voltage line may be electrically connected in the non-light-emitting area.

The display device may further include a second pixel row adjacent to the first pixel row, the first pixel row and the second pixel row being parallel to each other and extending along the first direction. The second high voltage line may be disposed between the first pixel row and the second pixel row.

The first pixel row and the second pixel row may be electrically connected to the second high voltage line disposed between the first pixel row and the second pixel row.

The display device may further include a plurality of pixel rows parallel to the first pixel row, and a plurality of second high voltage lines. The arrangement of the pixel rows and the second high voltage lines is repeated along the second direction.

According to yet another embodiment of the invention, a display device includes a substrate including a display area including a first pixel row including a plurality of pixels disposed in a first direction, and a non-display area surrounding the display area; a first conductive layer; a buffer layer on the first conductive layer; a semiconductor layer on the buffer layer; a first insulating layer on the semiconductor layer; a second conductive layer on the first insulating layer; a second insulating layer on the second conductive layer; a third conductive layer on the second insulating layer; and a high voltage line electrically connected to the first pixel row and extending in the first direction. The high voltage line is disposed in the first conductive layer, the second conductive layer, or the third conductive layer, and the high voltage line extends to the non-display area.

The display device may further include: a scan line electrically connected to the first pixel row; and a data line electrically connected to a first pixel column including pixels disposed along a second direction intersecting the first direction. The high voltage line may be disposed in the third conductive layer, the scan line may be disposed in the second conductive layer, and the data line may be disposed in the first conductive layer.

The display device may further include: a scan line electrically connected to the first pixel row; and a data line electrically connected to a first pixel column including pixels disposed along a second direction intersecting the first direction. The high voltage line may be disposed in the second conductive layer, the scan line may be disposed in the third conductive layer, and the data line may be disposed in the first conductive layer.

The display device may further include: a color filter on the third conductive layer; and a planarization layer on the color filter. Respective color filters disposed in the plurality of pixels may overlap each other at boundaries between the adjacent pixels.

The display device may further include an anode electrode disposed on the third conductive layer. The display area may include a light-emitting area and a non-light-emitting area surrounding the light-emitting area, and the anode electrode and the high voltage line may be electrically connected in the non-light-emitting area.

The display device may further include a second pixel row that is parallel to the first pixel row. The high voltage line may be disposed between the first pixel row and the second pixel row, and the first pixel row and the second pixel row may be electrically connected to the high voltage line.

According to yet another embodiment of the invention, a display device includes: a display panel including a display area including a plurality of pixels, and a non-display area surrounding the display area; a shorting bar arranged at one side of the display panel and extending along a first direction in the non-display area; a first high voltage line surrounding the display area in the non-display area and having both ends electrically connected to the shorting bar; and a second high voltage line extending across the display area and having both ends electrically connected to the first high voltage line, the second high voltage line being electrically connected to a first pixel row including the pixels disposed along the first direction, in which the both ends of the second high voltage line are electrically connected to the first high voltage line in the non-display area.

The display device may further include a second pixel row spaced apart from the first pixel row in a second direction crossing the first direction, in which the second high voltage line may extend between the first pixel row and the second pixel row and be electrically connected to subpixels in each of the first and second pixel rows.

The display device may further include a first signal line and a second signal line electrically connected to the first pixel row and the second pixel row, respectively, in which the first and second signal lines may be disposed between the first pixel row and the second pixel row, and the second high voltage line may be disposed between the first and second signal lines.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a schematic view showing a display device according to an embodiment of the invention.

FIG. 2 is a plan view showing a back surface of the display device according to an embodiment of the invention.

FIG. 3 is an equivalent circuit diagram constituting a pixel in the display device according to an embodiment of the invention.

FIG. 4 is a plan view showing a display panel according to an embodiment of the invention.

FIG. 5 is a plan view showing a display panel according to an embodiment of the invention.

FIG. 6 is a cross-sectional view along line A-A’ in FIG. 5.

FIG. 7 is a cross-sectional view along line B-B’ in FIG. 5.

FIG. 8 is a cross-sectional view along line B-B’ in FIG. 5 of a display panel according to another embodiment of the invention.

FIG. 9 is a plan view showing the display panel according to another embodiment of the invention.

FIG. 10 is a cross-sectional view along line C-C’ in FIG. 9.

FIG. 11 is a cross-sectional view along line C-C’ in FIG. 9 of the display panel according to another embodiment of the invention.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z – axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As is customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

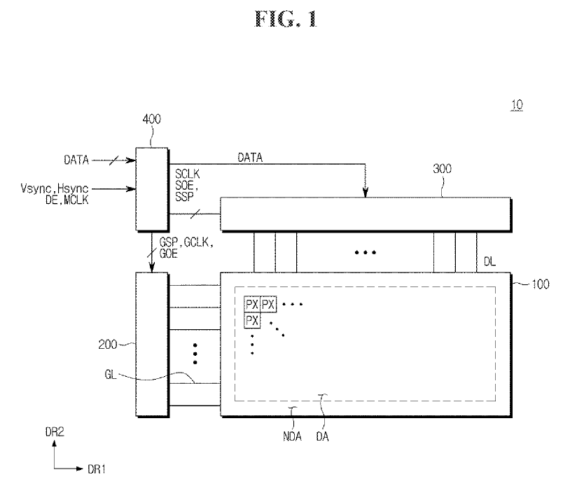

FIG. 1 is a schematic view showing a display device according to an embodiment of the invention.

Referring to FIG. 1, a display device 10 according to one embodiment may include a display panel 100 in which a plurality of gate lines GL and data lines DL are connected and a plurality of pixels PX are disposed, a gate driving circuit 200 for providing signals to the plurality of gate lines GL, a first circuit board 300 for supplying data voltages through the plurality of data lines DL, and a timing controller 400 for controlling the gate driving circuit 200 and the first circuit board 300.

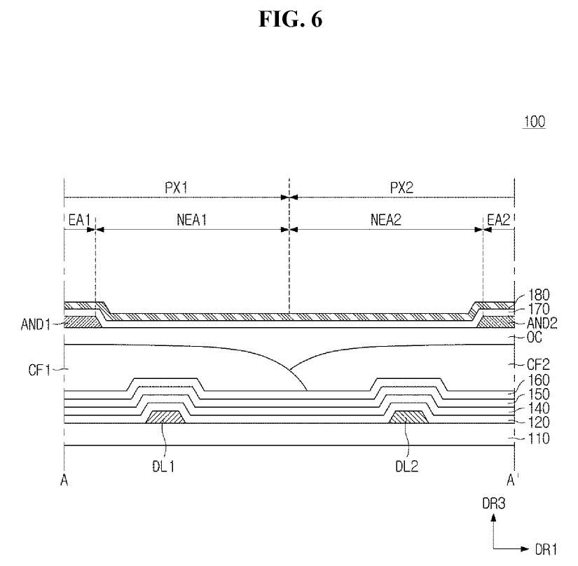

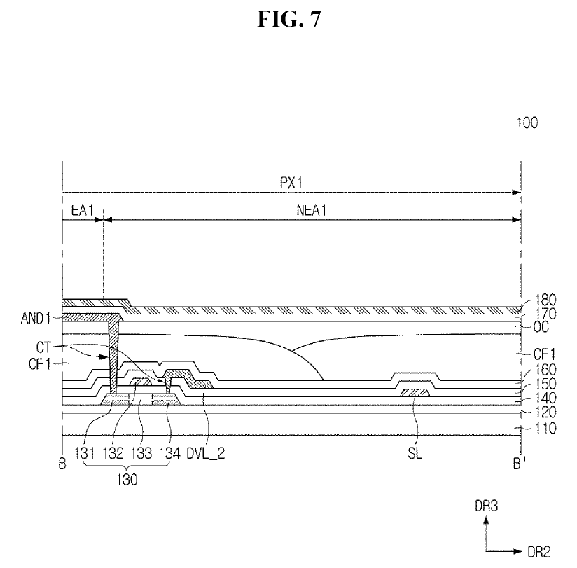

In embodiments, a first direction DR1 and a second direction DR2 are different directions and intersect each other, for example, vertically in a plan view. A third direction DR3 is a direction that intersects the plane on which the first direction DR1 and the second direction DR2 are present, for example, a direction perpendicular to both the first direction DR1 and the second direction DR2. In FIG. 1, the first direction DR1 may be the same as an extension direction of long sides of the display panel 100, the second direction DR2 may the same as an extension direction of short sides of the display panel 100, and the third direction DR3 may be the same as a stacking direction of a data line DL (see FIG. 6), a scan line SL (see FIG. 7), and a second high-voltage line DVL_2 (see FIG. 7). However, the directions described in the embodiments should be understood as indicating relative directions, and the embodiments are not limited to the described directions.

The display panel 100 displays images based on scan signals transmitted from the gate driving circuit 200 through the plurality of gate lines GL and data voltages transmitted from the first circuit board 300 through the plurality of data lines DL.

In the case of a liquid crystal display device, the display panel 100 may include a liquid crystal layer formed between two substrates and may operate in any known mode of a twisted nematic (TN) mode, a vertical alignment (VA) mode, an in plane switching (IPS) mode, a fringe field switching (FFS) mode, etc. On the other hand, in the case of an organic light-emitting diode display device, the display panel 100 may be implemented in a top emission manner, a bottom emission manner, a dual emission manner, etc.

The display panel 100 may include a plurality of pixels PX, each of which may be formed of pixels PX with different colors, for example, a white sub-pixel, a red sub-pixel, a green sub-pixel, and a blue sub-pixel and may be defined by the plurality of data lines DL and the plurality of gate lines GL.

One pixel PX may include a thin film transistor TFT disposed in an area formed by one data line DL and one gate line GL, a light-emitting element, such as a light-emitting diode that emits light according to a data voltage, a storage capacitor electrically connected to the light-emitting element to maintain a voltage, etc.

For example, when the display device 10 having the resolution of 2,600×3,840 is formed of four pixels PX of white W, red R, green G, and blue B, then 2,600 gate lines GL and 15,360 data lines DL (calculated as 3,840×4=15,360) may be provided. Each data line DL may be connected to one of the four pixels (white W, red R, green G, blue B), and each pixel PX may be disposed in an area formed by the gate lines GL and the data lines DL.

The gate driving circuit 200 is controlled by the timing controller 400 and controls driving timings of the plurality of pixels PX by sequentially outputting scan signals to the plurality of gate lines GL disposed on the display panel 100.

In the display device 10 having the resolution of 2,600×3,840, a case in which scan signals are sequentially output to 2,600 gate lines GL from the first gate line to the 2,600^{th} gate line may be referred to as “2,600-phase driving.” Alternatively, a case in which a scan signal is sequentially output in groups of four gate lines GL, such as when scan signals are sequentially output to the first gate line to the fourth gate line, followed by the fifth to eighth gate lines, and so on, is referred to as “4-phase driving.” That is, a case in which a scan signal is sequentially output per N gate lines GL may be referred to as “N-phase driving.”

In this case, the gate driving circuit 200 may include one or more gate driving integrated circuits GDIC, which may be located at only one side or both sides of the display panel 100 according to a driving method. Alternatively, the gate driving circuit 200 may be implemented in the form of a gate-in-panel (GIP) that is formed directly in a bezel area of the display panel 100.

The first circuit board 300 receives digital image data DATA from the timing controller 400 and converts the received digital image data DATA into an analog data voltage. Then, by outputting a data voltage to each data line DL according to the timing when the scan signal is applied through the gate line GL, each pixel PX connected to the data line DL displays a light-emitting signal having brightness corresponding to the data voltage.

Likewise, the first circuit board 300 may include one or more source driving integrated circuits SDIC, and the source driving integrated circuit SDIC may be connected to a bonding pad of the display panel 100 or disposed directly on the display panel 100 using a tape automated bonding (TAB) method or a chip on substrate glass (COG) method.

In some cases, each source driving integrated circuit SDIC may be disposed integrally with the display panel 100. In addition, each source driving integrated circuit SDIC may be implemented using a chip-on-film (COF) method, and in this case, each source driving integrated circuit SDIC may be mounted on a circuit film and electrically connected to the data line DL of the display panel 100 through the circuit film.

The timing controller 400 supplies various control signals to the gate driving circuit 200 and the first circuit board 300, and controls the operations of the gate driving circuit 200 and the first circuit board 300. That is, the timing controller 400 controls the gate driving circuit 200 to output the scan signals according to the timing implemented in each frame, and on the other hand, the timing controller 400 transmits the digital image data DATA received from the outside to the first circuit board 300.

In this case, the timing controller 400 receives various timing signals including a vertical synchronization signal Vsync, a horizontal synchronization signal Hsync, a data enable signal DE, a main clock MCLK, and the like together with the digital image data DATA from the outside (e.g., a host system). Accordingly, the timing controller 400 generates the control signals using various timing signals received from the outside and transmits the control signals to the gate driving circuit 200 and the first circuit board 300.

For example, the timing controller 400 outputs various gate control signals including a gate start pulse GSP, a gate clock GCLK, a gate output enable signal GOE, and the like to control the gate driving circuit 200. Here, the gate start pulse GSP controls the timing when one or more gate driving integrated circuits GDIC constituting the gate driving circuit 200 start to operate. In addition, the gate clock GCLK is a clock signal input in common with the one or more gate driving integrated circuits GDIC and controls the shift timing of the scan signal. In addition, the gate output enable signal GOE specifies timing information of the one or more gate driving integrated circuits GDIC.

In addition, the timing controller 400 outputs various data control signals including a source start pulse SSP, a source sampling clock SCLK, a source output enable signal SOE, and the like in order to control the first circuit board 300. Here, the source start pulse SSP controls the timing when one or more source driving integrated circuits SDIC constituting the first circuit board 300 start to sample data. The source sampling clock SCLK is a clock signal that controls the timing that samples data in the source driving integrated circuit SDIC. The source output enable signal SOE controls the output timing of the first circuit board 300.

The display device 10 may further include a power management integrated circuit for supplying various voltages or currents to the display panel 100, the gate driving circuit 200, the first circuit board 300, and the like for controlling various voltages or currents, which will be supplied.

A light-emitting element may be disposed in each pixel PX. For example, an OLED display device may include a light-emitting element, such as a light-emitting diode, in each pixel PX and display images by controlling a current flowing in the light-emitting element according to a data voltage.

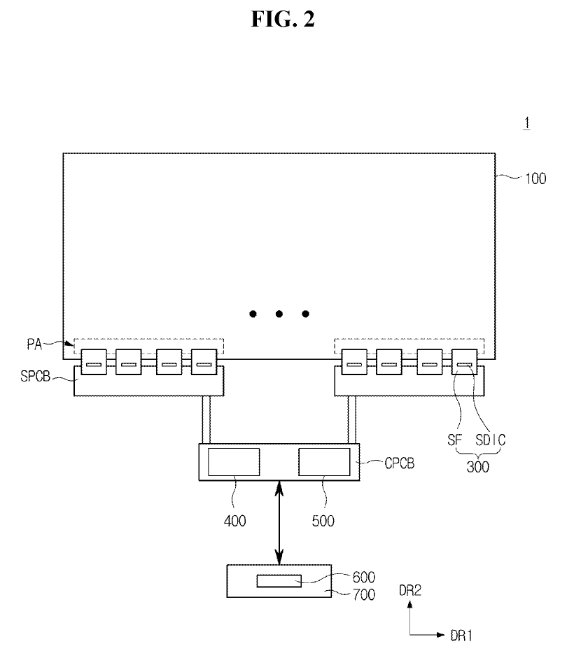

FIG. 2 is a plan view showing a back surface of the display device 10 according to one embodiment.

Referring to FIG. 2, the display device 10 according to one embodiment shows a case in which the source driving integrated circuit SDIC included in the first circuit board 300 is implemented using the COF method among various methods (TAB, COG, COF, and the like), and the gate driving circuit 200 is implemented using the GIP method among various types (TAB, COG, COF, GIP, and the like).

When the gate driving circuit 200 (see FIG. 1) is implemented using the GIP method, a plurality of gate driving integrated circuits GDIC included in the gate driving circuit 200 may be formed directly in the bezel area of the display panel 100. In this case, the gate driving integrated circuit GDIC may receive various signals (a clock signal, a gate high signal, a gate low signal, and the like) required for generating a scan signal SCAN through gate driving- related signal lines disposed in the bezel area.

Likewise, each of one or more source driving integrated circuits SDIC included in the first circuit board 300 may be mounted on a source film SF, and one side of the source film SF may be electrically connected to the display panel 100. In addition, lines for electrically connecting the source driving integrated circuit SDIC to the display panel 100 may be disposed on the source film SF.

The display device 10 may include at least one source printed circuit board SPCB (or a second circuit board) and a control printed circuit board CPCB (or a third circuit board) on which control components and various electrical components are mounted in order to connect the plurality of source driving integrated circuits SDIC to other devices in a circuitry manner.

In this case, the other side of the source film SF on which the source driving integrated circuit SDIC is mounted may be connected to the at least one source printed circuit board SPCB. That is, the source film SF on which the source driving integrated circuit SDIC is mounted may have one side electrically connected to the display panel 100 and the other side electrically connected to the source printed circuit board SPCB. For example, a plurality of source films SF may be connected to one source printed circuit board SPCB, but are not limited thereto.

The timing controller 400 and a power management integrated circuit (PMIC) 500 may be mounted on the control printed circuit board CPCB. The timing controller 400 may control the operations of the first circuit board 300 and the gate driving circuit 200. The PMIC 500 may supply a driving voltage or current to the display panel 100, the first circuit board 300, the gate driving circuit 200, and the like and control the voltage or current being supplied.

The at least one source printed circuit board SPCB and the control printed circuit board CPCB may be connected through at least one connecting member in a circuitry manner, and the connecting member may include, for example, a flexible printed circuit (FPC), a flexible flat cable (FFC), etc. For example, the source printed circuit board SPCB may be provided as a plurality of source printed circuit boards, and the plurality of source printed circuit boards SPCB may be connected to one control printed circuit board CPCB. In this case, one source printed circuit board SPCB may be connected to the control printed circuit board CPCB through a plurality of flexible flat cables FFC.

The display device 10 may further include a set board 700 electrically connected to the control printed circuit board CPCB. In this case, the set board 700 may also be referred to as a “power board”. The set board 700 may include a main power management circuit (M-PMC) 600 for managing the overall power of the display device 10. The M-PMC 600 may be linked with the PMIC 500.

In the case of the display device 10 having the above configuration, the driving voltage is generated from the set board 700 and transmitted to the PMIC 500 in the control printed circuit board CPCB. The PMIC 500 transmits a driving voltage required for display driving or characteristic value sensing to the source printed circuit board SPCB through the flexible printed circuit FPC or the flexible flat cable FFC. The driving voltage transmitted to the source printed circuit board SPCB is supplied to emit light from or sense a specific pixel PX within the display panel 100 through the source driving integrated circuit SDIC.

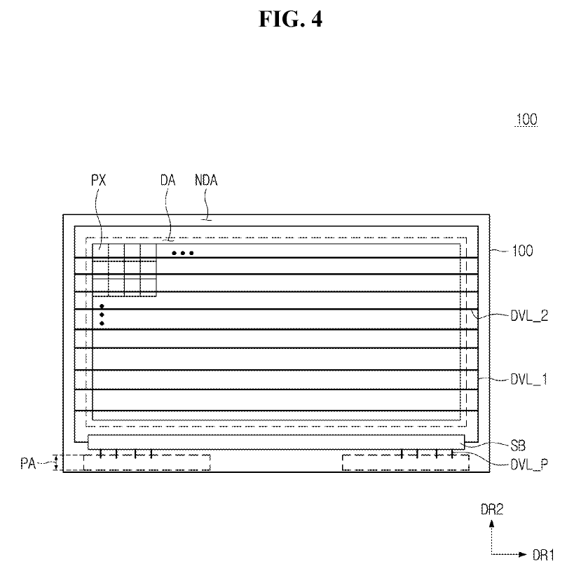

Although not shown, the driving voltage may be supplied to the pixel PX along a pad high-voltage line DVL_P, a shorting bar SB, high-voltage lines DVL_1, and DVL_2 (see FIG. 4) within the display panel 100.

In this case, each pixel PX arranged on the display panel 100 within the display device 10 may include a light-emitting element and circuit elements, such as a driving transistor for driving the light-emitting element and the like.

The type and number of circuit elements forming each pixel PX may be determined in various ways according to a providing function, a design method, etc.

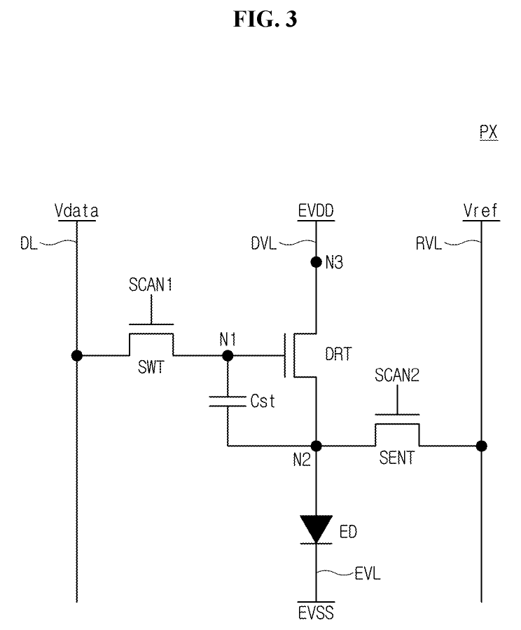

FIG. 3 is an equivalent circuit diagram constituting a pixel in the display device according to an embodiment of the invention.

Referring to FIG. 3, in the display device 10 according to one embodiment, the pixel PX may include one or more transistors and a capacitor, and an organic light-emitting diode may be disposed as a light-emitting element ED.

For example, the pixel PX may include a driving transistor DRT, a switching transistor SWT, a sensing transistor SENT, a storage capacitor Cst, and the light-emitting element ED.

The driving transistor DRT has a first node N1, a second node N2, and a third node N3. The first node N1 of the driving transistor DRT may be a gate node to which the data voltage Vdata is applied from the first circuit board 300 through the data line DL when the switching transistor SWT is turned on. The second node N2 of the driving transistor DRT may be electrically connected to an anode electrode of the light-emitting element ED, and may be a source node or a drain node. The third node N3 of the driving transistor DRT may be electrically connected to a driving voltage line DVL to which a driving voltage EVDD is applied, and may be a drain node or a source node.

In this case, during a display driving period, the driving voltage EVDD required to display an image may be supplied to the driving voltage line DVL and, for example, the driving voltage EVDD required to display an image may be 27 V.

The switching transistor SWT is electrically connected between the first node N1 of the driving transistor DRT and the data line DL, and has a gate node connected to the gate line GL to operate according to the scan signal SCAN supplied through the gate line GL. In addition, when the switching transistor SWT is turned on, the operation of the driving transistor DRT is controlled by transmitting the data voltage Vdata supplied through the data line DL to the gate node of the driving transistor DRT.

The sensing transistor SENT is electrically connected between the second node N2 of the driving transistor DRT and a reference voltage line RVL, and has a gate node connected to the gate line GL to operate according to a sense signal SENSE supplied through the gate line GL. When the sensing transistor SENT is turned on, a reference voltage (sensing reference voltage) Vref supplied through the reference voltage line RVL is transmitted to the second node N2 of the driving transistor DRT.

That is, a voltage of the first node N1 and a voltage of the second node N2 of the driving transistor DRT are controlled by controlling the switching transistor SWT and the sensing transistor SENT, thereby allowing a current for driving the light-emitting element ED to be supplied.

The gate nodes of the switching transistor SWT and the sensing transistor SENT may be connected together to one gate line GL or connected to different gate lines GL, respectively. In FIG. 3, a structure in which the switching transistor SWT and the sensing transistor SENT are connected to different gate lines GL, respectively, is exemplarily shown, and in this case, the switching transistor SWT and the sensing transistor SENT may be independently controlled by the scan signal SCAN and the sense signal SENSE that are transmitted through the different gate lines GL.

On the other hand, when the switching transistor SWT and the sensing transistor SENT are connected to one gate line GL, the switching transistor SWT and the sensing transistor SENT may be simultaneously controlled by the scan signal SCAN or the sense signal SENSE transmitted through one gate line GL, and an aperture ratio of the pixel PX can be increased.

The transistors disposed in the pixel PX may be formed as an n-type transistor or a p-type transistor, and here, an example in which the transistors are formed as an n-type transistor is shown. However, the inventive concepts are not limited thereto, and in other embodiments, some of the transistors in the pixel PX may be formed as an n-type transistor and a p-type transistor, or p-type transistors only.

The storage capacitor Cst is electrically connected between the first node N1 and the second node N2 of the driving transistor DRT and maintains the data voltage Vdata during one frame.

In some embodiments, the storage capacitor Cst may be connected between the first node N1 and the third node N3 of the driving transistor DRT according to the type of the driving transistor DRT. The anode electrode of the light-emitting element ED may be electrically connected to the second node N2 of the driving transistor DRT, and a base voltage EVSS supplied through a base voltage line EVL may be applied to a cathode electrode of the light-emitting element ED.

Here, the base voltage EVSS may be a ground voltage or a voltage higher or lower than the ground voltage. In addition, the base voltage EVSS may vary depending on a driving state, and for example, the base voltage EVSS at the time of display driving and the base voltage EVSS at the time of sensing driving may be set to be different from each other.

The above structure of the pixel PX has three transistors (3T) and one capacitor (1C), that is, a 3T-1C structure, which is only an example for description, and the pixel PX may further include one or more transistors or in some cases, one or more capacitors. Alternatively, each of the plurality of pixels PX may have the same structure, or some pixels PX may have different structures.

In order to effectively sense the characteristic value of the driving transistor DRT, such as a threshold voltage or mobility, the display device 10 according to one embodiment may use a method of measuring a flowing current using a voltage charged in the storage capacitor Cst in a characteristic value sensing section of the driving transistor DRT, which is referred to as “current sensing”.

That is, by measuring the flowing current using the voltage charged in the storage capacitor Cst in the characteristic value sensing section of the driving transistor DRT, the characteristic value or a change in the characteristic value of the driving transistor DRT within the pixel PX may be identified.

In this case, since the reference voltage line RVL not only serves to transmit the reference voltage Vref but also serves as a sensing line for sensing the characteristic value of the driving transistor DRT within the pixel PX, the reference voltage line RVL may be referred to as a sensing line.

FIG. 4 is a plan view showing a display panel according to one embodiment.

Referring to FIG. 4, the display panel 100 may include a display area DA and a non-display area NDA surrounding the display area DA, and the display area DA may include a plurality of pixels PX.

The driving voltage EVDD transmitted to the first circuit board 300 (see FIG. 2) may be applied to each pixel PX of the display area DA via a pad high voltage line DVL_P, a shorting bar SB, a first high voltage line DVL_1, and a second high voltage line DVL_2.

The pad high voltage line DVL_P may be provided as a plurality of pad high voltage lines. One sides of the plurality of pad high voltage lines DVL_P may be connected to the first circuit board 300 (see FIG. 2) in a pad area PA, and the other sides may be connected to the shorting bar SB. Accordingly, the plurality of pad high voltage lines DVL_P may transmit the driving voltage EVDD transmitted from the first circuit board 300 (see FIG. 2) to the shorting bar SB.

The shorting bar SB may be disposed to extend along the first direction DR1 in the non-display area NDA, which is located at one side of the display panel 100 in the second direction DR2.

One side of the first high voltage line DVL_1 may be connected to one side of the shorting bar SB extending in the first direction DR1, and the connected first high voltage line DVL_1 may be disposed in the non-display area NDA and disposed to surround the display area DA along the non-display area NDA. The other side of the first high voltage line DVL_1 surrounding the display area DA may be connected to the other side of the shorting bar SB extending in the first direction DR1.

The second high voltage line DVL_2 may be provided as a plurality of second high voltage lines, and both ends of the plurality of second high voltage lines DVL_2 may be electrically connected to the first high voltage line DVL_1 disposed in the non-display area NDA extending in the second direction DR2. That is, the second high voltage lines DVL_2 may extend in the first direction DR1 and disposed in the display area DA, and the one side and the other side of the second high voltage line DVL_2 in the first direction DR1 may each extend to the non-display area NDA and may be electrically connected to the first high voltage line DVL_1 extending in the non-display area NDA along the second direction DR2.

The plurality of pixels PX disposed in the display area DA may be disposed in a matrix manner in the first direction DR1 and the second direction DR2. Accordingly, a plurality of adjacent pixels PX disposed in the first direction DR1 may form pixel rows, and a plurality of adjacent pixels PX disposed in the second direction DR2 may form pixel columns. That is, the pixel rows may be repeatedly disposed in the second direction DR2, and the pixel columns may be repeatedly disposed in the first direction DR1. However, the inventive concepts are not limited to a particular arrangement of the plurality of pixels PX, and in some embodiments, the plurality of pixels PX may be arranged differently from the matrix manner.

The second high voltage lines DVL_2 may be disposed to overlap the pixel rows in the first direction DR1, and thus may be connected to each pixel PX included in the pixel rows.

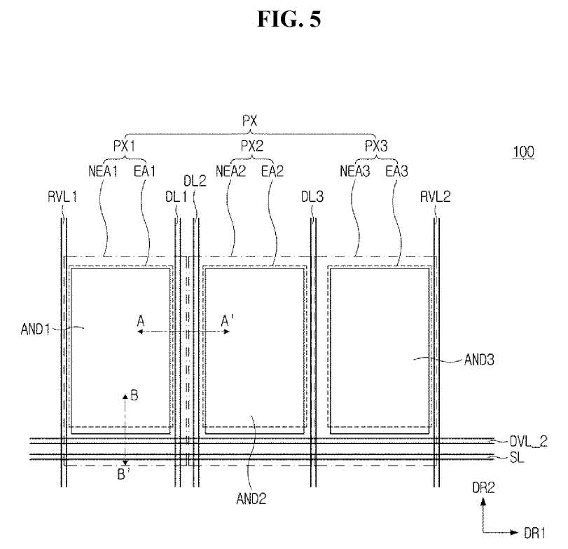

FIG. 5 is a plan view showing a display panel according to one embodiment.

Referring to FIG. 5, the pixel PX may include a first sub-pixel PX1, a second sub-pixel PX2, and a third sub-pixel PX3. The first sub-pixel PX1 may include a first light-emitting area EA1 and a first non-light-emitting area NEA1 around the first light-emitting area EA1, the second sub-pixel PX2 may include a second light-emitting area EA2 and a second non-light-emitting area NEA2 around the second light-emitting area EA2, and the third sub-pixel PX3 may include a third light-emitting area EA3 and a third non-light-emitting area NEA3 around the third light-emitting area EA3. That is, the non-light-emitting area NEA1, NEA2, and NEA3 may correspond one-to-one to boundaries between adjacent sub-pixels PX1, PX2, and PX3.

Anode electrodes AND1, AND2, and AND3 may be disposed in the sub-pixels PXb, PX2, and PX3, respectively. The anode electrodes AND1, AND2, and AND3 may be disposed across the entire light-emitting areas EA1, EA2, and EA3, and portions thereof may be disposed in the non-light-emitting areas NEA1, NEA2, and NEA3. Areas of the anode electrodes AND1, AND2, and AND3 respectively disposed in the light-emitting area EA1, EA2, and EA3 may be larger than areas of the anode electrodes AND1, AND2, and AND3 respectively disposed in the non-light-emitting areas NEA1, NEA2, and NEA3.

Data lines DL1, DL2, and DL3 extending in the second direction DR2 extending in the second direction DR2 may be disposed between the anode electrodes AND1, AND2, and AND3. The reference voltage lines RVL1 and RVL2 may also extend in the second direction DR2.

The reference voltage lines RVL1 and RVL2 and the data lines DL1, DL2, and DL3 may be disposed in the non-light-emitting areas NEA1, NEA2, and NEA3 of the sub-pixels PX1, PX2, and PX3, respectively.

A first reference voltage line RVL1 may be disposed on one side of a first anode electrode AND1 in the first direction DR1, and a first data line DL1 and a second data line DL2 may be disposed on the other side. The first data line DL1 and the second data line DL2 may be disposed on one side of the second anode electrode AND2 in the first direction DR1, and the third data line DL3 may be disposed on the other side. The third data line DL3 may be disposed on one side of the third anode electrode AND3 in the first direction DR1, and the second reference voltage line RVL2 may be disposed on the other side.

That is, the first data line DL1 and the second data line DL2 may be disposed between the first anode electrode AND1 and the second anode electrode AND2, and the third data line DL3 may be disposed between the second anode electrode AND2 and the third anode electrode AND3. The first data line DL1 may be disposed between the second data line DL2 and

the first anode electrode AND1, and the second data line DL2 may be disposed between the second anode electrode AND2 and the first data line DL1.

The second high voltage line DVL_2 may be disposed on the one sides of the anode electrodes AND1, AND2, and AND3 in the second direction DR2. The second high voltage line DVL_2 may extend in the first direction DR1 and thus, may be electrically connected to the anode electrodes AND1, AND2, and AND3 disposed in the first direction DR1 in the non-light-emitting areas NEA1, NEA2, and NEA3. The detailed description thereof will be made below in FIG. 7.

Scan lines SL extending in the first direction DR1 may be disposed on one side of the second high voltage line DVL_2 in the second direction DR2. That is, the second high voltage line DVL_2 may be disposed between the anode electrodes AND1, AND2, and AND3 and the scan lines SL. The scan line SL is a type of gate line GL (see FIG. 1) and may be a line that transmits a scan signal. The second high voltage line DVL_2 and the scan line SL may be disposed across the non-light-emitting areas NEA1, NEA2, and NEA3 of the sub-pixels PX1, PX2, and PX3.

FIG. 6 is a cross-sectional view along line A-A’ in FIG. 5.

Referring to FIG. 6, the display panel 100 may include a substrate 110, a first conductive layer, a buffer layer 120, a first insulating layer 140, a second insulating layer 150, a third insulating layer 160, color filters CF1 and CF2, a planarization layer OC, the anode electrodes AND1 and AND2, an organic layer 170, and a cathode electrode 180.

The substrate 110 may be formed of a material such as glass or plastic. In particular, in an OLED display device with a bottom-emitting structure, the substrate 110 may be formed of a transparent material because light that has passed through the color filter CF needs to be emitted to the outside, but the embodiments of the invention are not limited thereto.

The first conductive layer may be disposed on the substrate 110. The first conductive layer may be formed of a single layer or multiple layers formed of one of molybdenum (Mo), aluminum (Al), chromium (Cr), nickel (Ni), neodymium (Nd), and copper (Cu) or an alloy thereof, but the embodiments of the invention are not limited thereto.

The first conductive layer may include a first data line DL1 and a second data line DL2. The first data line DL1 may be disposed in the first non-light-emitting area NEA1, and the second data line DL2 may be disposed in the second non-light-emitting area NEA2. Although not shown, the third data line DL3 (see FIG. 5) may be disposed in the third non-light-emitting area NEA3 (see FIG. 5).

The buffer layer 120 may be disposed on the first conductive layer. The buffer layer 120 can minimize or delay the diffusion of moisture or oxygen penetrating the substrate 110 and prevent a short circuit between the first conductive layer and a semiconductor layer 133 (see FIG. 7) to be described below. The buffer layer 120 may be formed by alternately stacking silicon nitride (SiNₓ) and silicon oxide (SiOₓ) at least once, but the embodiments of the invention are not limited thereto.

The first insulating layer 140 may be disposed on the buffer layer 120. The first insulating layer 140 can prevent short circuits between the semiconductor layer 133 (see FIG. 7) and other components of the thin film transistors (for example, a source electrode 131, a gate electrode 132, and a drain electrode 134) (see FIG. 7) to be described below. The first insulating layer 140 may be formed of the same material as the buffer layer 120, but the embodiments of the invention are not limited thereto. For example, the first insulating layer 140 may be formed of an inorganic insulation material, such as silicon nitride (SiNₓ) or silicon oxide (SiOₓ), but the embodiments of the invention are not limited thereto.

The second insulating layer 150 may be disposed on the first insulating layer 140. The second insulating layer 150 may be formed by alternately stacking silicon nitride (SiNₓ) and silicon oxide (SiOₓ) at least once, but the embodiments of the invention are not limited thereto.

The third insulating layer 160 may be disposed on the second insulating layer 150. The third insulating layer 160 may be formed of the same material as the first insulating layer 140 or the second insulating layer 150, but the embodiments of the invention are not limited thereto.

The color filters CF1 and CF2 may be disposed on the third insulating layer 160. A first color filter CF1 may be disposed in the first sub-pixel PX1, and a second color filter CF2 may be disposed in the second sub-pixel PX2. Although not shown, a third color filter may be disposed in the third sub-pixel PX3 (see FIG. 5).

The color filters CF1 and CF2 may block a specific color of light emitted from the light-emitting areas EA1 and EA2 of the sub-pixels PX1 and PX2. The first color filter CF1 may be provided to block light of the remaining colors excluding red (R) light. In this case, the first color filter CF1 may be provided as a red color filter. The second color filter CF2 may be provided to block light of the remaining colors excluding green (G) light. In this case, the second color filter CF2 may be provided as a green color filter. Although not shown, the color filter provided in the third sub-pixel PX3 (see FIG. 5) may be provided to block light of the remaining colors excluding blue (B) light, and in this case, the color filter may be provided as a blue color filter. However, the embodiments of the invention are not limited thereto.

The color filters CF1 and CF2 may overlap each other in a thickness direction (e.g., the third direction DR3) at the boundary between adjacent sub-pixels PX1 and PX2. However, the embodiments of the invention are not limited thereto, and the color filters CF1 and CF2 may be spaced apart from each other.

The planarization layer OC may be disposed on the color filters CF1 and CF2. The planarization layer OC may serve to planarize a step formed by the color filters CF1 and CF2. The planarization layer OC may include an organic insulation material.

The anode electrodes AND1 and ANDb may be disposed on the planarization layer OC. The first anode electrode AND1 may be disposed in the first sub-pixel PX1, and more specifically, in the first light-emitting area EA1. The second anode electrode AND2 may be disposed in the second sub-pixel PX2, and more specifically, in the second light-emitting area EA2. The anode electrodes AND1 and AND2 may be transparent electrodes that transmit light, but the embodiments of the invention are not limited thereto. For example, the anode electrodes AND1 and AND2 may include a transparent conductive material such as indium tin oxide (ITO) or indium zinc oxide (IZO) or a metal that transmits visible light, but the embodiments of the invention are not limited thereto.

The organic layer 170 may be disposed across the anode electrodes AND1 and ANDb and the planarization layer OC on which the anode electrodes ANDb and AND2 are not disposed. The organic layer 170 may include one or more light-emitting structures (or light-emitting elements or elements) stacked in the order or reverse order of a hole transport layer and an electron transport layer. For example, the hole transport layer may include a hole transfer layer, a hole injecting layer, an electron blocking layer, a P-type charge generation layer, or the like, but the embodiments of the invention are not limited thereto, and the electron transport layer may include an electron transfer layer, an electron injecting layer, a hole blocking layer, an N-type charge generation layer, or the like, but the embodiments of the invention are not limited thereto. The organic layer 170 may be an organic light-emitting layer.

The cathode electrode 180 may be disposed on the organic layer 170. The cathode electrode 180 may be a reflective electrode that reflects light, but the embodiments of the invention are not limited thereto. The cathode electrode 180 may include a metal material with high reflectivity, such as a stacked structure (Ti/Al/Ti) of aluminum (Al) and titanium (Ti), a stacked structure (ITO/Al/ITO) of aluminum (Al) and indium tin oxide (ITO), or an APC alloy, and may be formed of a single layer or multiple layers, but the embodiments of the invention are not limited thereto.

FIG. 7 is a cross-sectional view along line B-B’ in FIG. 5.

Referring to FIG. 7, the buffer layer 120 may be disposed on the substrate 110, and the thin film transistor 130 may be disposed between the buffer layer 120 and the second insulating layer 150. The thin film transistor 130 may be a driving transistor DRT (see FIG. 3) and may include a source electrode 131, a gate electrode 132, the semiconductor layer 133, and a drain electrode 134.

The source electrode 131, the semiconductor layer 133, and the drain electrode 134 may be disposed between the buffer layer 120 and the first insulating layer 140, and each may be disposed in the first non-light-emitting area NEA1 of the first sub-pixel PX1.

The semiconductor layer 133 may include a metal oxide semiconductor, such as indium-gallium-zinc oxide (IGZO), and a silicon-based semiconductor material, such as amorphous silicon or polycrystalline silicon, but the embodiments of the invention are not limited thereto.

Since the polycrystalline semiconductor layer has higher mobility than the amorphous semiconductor layer and the oxide semiconductor layer, power consumption can be less, and reliability can be excellent. Accordingly, the semiconductor layer 133 may be formed as a polycrystalline semiconductor layer.

The source electrode 131 may be disposed on one side of the semiconductor layer 133 in the second direction, and the drain electrode 134 may be disposed on the other side. The source electrode 131 and the drain electrode 134 may be formed of a metallic material. For example, the source electrode 131 and the drain electrode 134 may be formed of a single layer or multiple layers formed of one of molybdenum (Mo), aluminum (Al), chromium (Cr), gold (Au), titanium (Ti), nickel (Ni), neodymium (Nd), and copper (Cu) or an alloy thereof, but the embodiments of the invention are not limited thereto.

The first insulating layer 140 may be disposed on the source electrode 131, the semiconductor layer 133, and the drain electrode 134, thereby preventing a short circuit between the components (the source electrode 131, the semiconductor layer 133, and the drain electrode 134) and the gate electrode 132.

The second conductive layer may be disposed between the first insulating layer 140 and the second insulating layer 150. The second conductive layer may include the gate electrode 132 and the scan line SL.

The gate electrode 132 may be disposed to overlap the semiconductor layer 133. The gate electrode 132 may be formed of a single layer or multiple layers made of molybdenum (Mo), copper (Cu), titanium (Ti), aluminum (Al), chromium (Cr), gold (Au), nickel (Ni), neodymium (Nd), or a compound thereof, but the embodiments of the invention are not limited thereto.

The scan line SL may be disposed to be spaced apart from the gate electrode 132. The scan line SL and the gate electrode 132 may be disposed in the first non-light-emitting area NEA1 of the first sub-pixel PX1.

The second insulating layer 150 may be disposed between the second conductive layer and the third conductive layer, thereby preventing a short circuit between the gate electrode 132 and the second high voltage line DVL_2.

The third conductive layer may be disposed between the second insulating layer 150 and the third insulating layer 160 and may include the second high voltage line DVL_2. The second high voltage line DVL_2 may be disposed in the first non-light-emitting area NEA1 of the first sub-pixel PX1. The second high voltage line DVL_2 may be electrically connected to the drain electrode 134 through a contact hole CT. The contact hole CT may be formed by passing through the second insulating layer 150 and the first insulating layer 140 in the third direction DR3, and an interior of the contact hole CT may be filled with the same material as the second high voltage line DVL_2, but the embodiments of the invention are not limited thereto. In some embodiments, the contact hole CT may be filled with the same material as the drain electrode 134.

The second high voltage line DVL_2 is exemplarily shown in FIG. 7 as being disposed in the third conductive layer, but in some embodiments, the second high voltage line DVL_2 may be disposed in the first conductive layer. In this case, the contact hole CT may be formed by passing through the buffer layer 120 and, likewise, may be electrically connected to the drain electrode 134 through the contact hole CT.

The third insulating layer 160 may be disposed on the third conductive layer, and the first color filter CF1 may be disposed on the third insulating layer 160. In one embodiment, the plurality of first color filters CF1 disposed along the pixel column may be first color filters CF1 that transmit the same color. Accordingly, the first color filter CF1 disposed on the second high voltage line DVL_2 and the first color filter CF1 disposed on the scan line SL may transmit the same color. However, the invention is not limited thereto, and the first color filters CF1 may transmit different colors. The plurality of first color filters CF1 disposed along the pixel column may overlap each other in the thickness direction (e.g., the third direction DR3) in the first non-light-emitting area NEA1 of the first sub-pixel PX1. However, the embodiments of the invention are not limited thereto, and the plurality of first color filters CF1 may be spaced apart from each other.

The planarization layer OC may be disposed on the first color filter CF1, and the first anode electrode AND1 may be disposed between the planarization layer OC and the organic layer 170. The first anode electrode AND1 may be disposed across the first light-emitting area EA1 and the first non-light-emitting area NEA1 of the first sub-pixel PX1. That is, the first anode electrode AND1 may be disposed in the first light-emitting area EA1 and may extend in the second direction DR2, and one side of the extended first anode electrode AND1 may extend to the first non-light-emitting area NEA1. In this case, an area of the first anode electrode AND1 disposed in the first light-emitting area EA1 may be larger than an area of the first anode electrode AND1 disposed in the first non-light-emitting area NEA1.

The first anode electrode AND1 may be electrically connected to the source electrode 131 through the contact hole CT. In this case, the contact hole CT may be formed by passing through the planarization layer OC, the first color filter CF1, the third insulating layer 160, the second insulating layer 150, and the first insulating layer 140. The interior of the contact hole CT may be filled with the same material as the first anode electrode AND1, but the embodiments of the invention are not limited thereto, and the interior of the contact hole CT may be, for example, filled with the same material as the source electrode 131.

The organic layer 170 may be disposed on the first anode electrode AND1 and the planarization layer OC on which the first anode electrode AND1 is not disposed, and the cathode electrode 180 may be disposed on the organic layer 170. Since the remaining parts have been described above in FIG. 6, the detailed descriptions thereof will be omitted below.

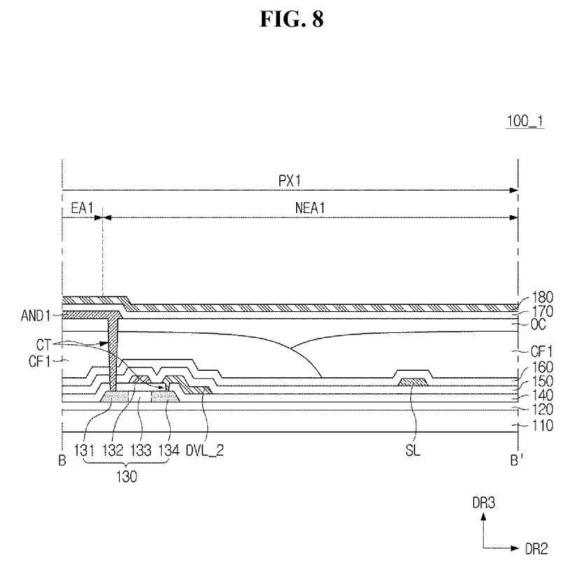

FIG. 8 is a cross-sectional view along line B-B’ in FIG. 5 of a display panel 100_1 according to another embodiment.

Referring to FIG. 8, the second high voltage line DVL_2 may be disposed in the second conductive layer. That is, the second high voltage line DVL_2 may be disposed between the first insulating layer 140 and the second insulating layer 150. Accordingly, the contact hole CT connecting the second high voltage line DVL_2 to the drain electrode 134 may be formed by passing through only the first insulating layer 140.

The scan line SL may be disposed in the third conductive layer. That is, the scan line SL may be disposed between the second insulating layer 150 and the third insulating layer 160.

The second high voltage line DVL_2 and the scan line SL may be disposed in the first non-light-emitting area NEA1 of the first sub-pixel PX1. Since the remaining parts have been described above in FIG. 6, the detailed descriptions thereof will be omitted below.

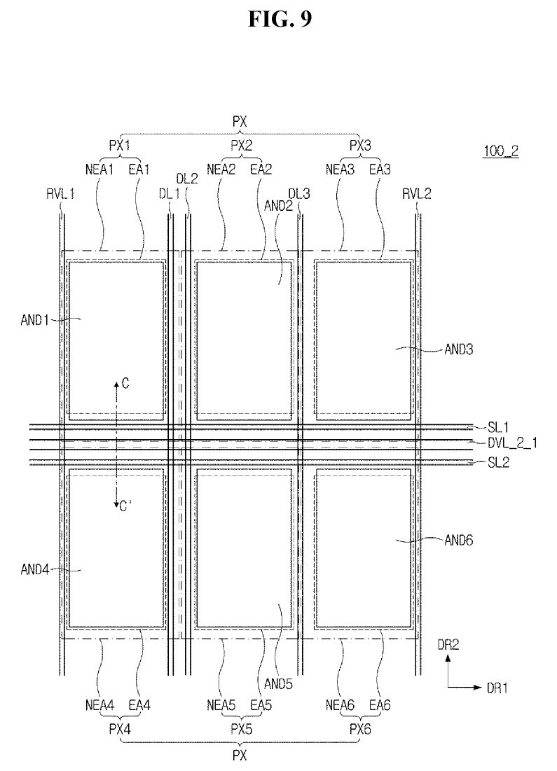

FIG. 9 is a plan view showing the display panel according to another embodiment.

Referring to FIG. 9, each of the pixels PX of a display panel 100_2 may include sub-pixels PX1, PX2, PX3, PX4, PX5, and PX6. For example, a first sub-pixel PX1, a second sub-pixel PX2, and a third sub-pixel PX3 may form one pixel PX, and a fourth sub-pixel PX4, a fifth sub-pixel PX5, and a sixth sub-pixel PX6 may form another pixel PX. The fourth sub-pixel PX4 may include a fourth light-emitting area EA4 and a fourth non-light-emitting area NEA4 around the fourth light-emitting area EA4, the fifth sub-pixel PX5 may include a fifth light-emitting area EA5 and a fifth non-light-emitting area NEA5 around the fifth light-emitting area EA5, and the sixth sub-pixel PXb may include a sixth light-emitting area EA6 and a sixth non-light-emitting area NEA6 around the sixth light-emitting area EA6.

In this case, a first scan line SL1, a second high voltage line DVL_2_1, and a second scan line SL2 may be disposed between adjacent sub-pixels PX1, PX2, PX3, PX4, PX5, and PX6 in the second direction DR2. That is, the first scan line SL1, the second high voltage line DVL_2_1, and the second scan line SL2 may be disposed between the first sub-pixel PX1 and the fourth sub-pixel PX4, between the second sub-pixel PX2 and the fifth sub-pixel PX5, and between the third sub-pixel PX3 and the sixth sub-pixel PX6.

The first scan line SL1 may be disposed between the first anode electrode AND1, the second anode electrode AND2, and the third anode electrode AND3, which are disposed to be spaced apart from each other in the first direction DR1 and the second high voltage line DVL_2_1. The second high voltage line DVL_2_1 may be disposed between the first scan line SL1 and the second scan line SL2, and the second scan line SL2 may be disposed between the fourth anode electrode AND4, the fifth anode electrode AND5, and the sixth anode electrode AND6, which are disposed to be spaced apart from each other in the first direction DR1, and the second high voltage line DVL_2_1.

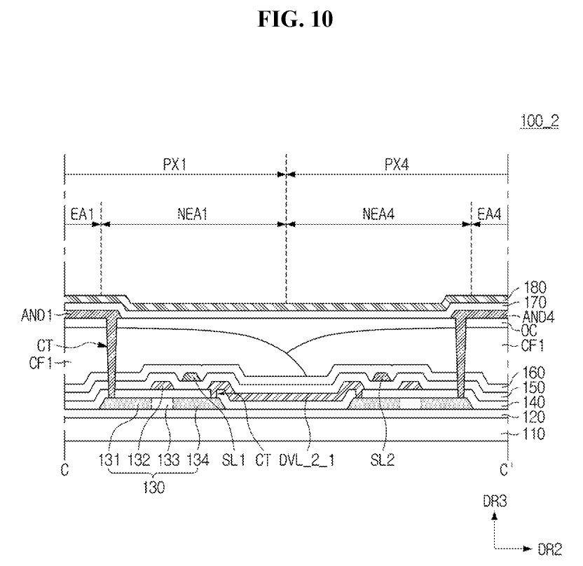

The first scan line SL1 may be disposed in adjacent non-light-emitting areas NEA1, NEA2, and NEA3 disposed in the first direction DR1, the second scan line SL2 may be disposed in adjacent non-light-emitting areas NEA4, NEA5, and NEA6 disposed in the first direction DR1, and the second high voltage line DVL_2_1 may be disposed across adjacent non- light-emitting areas NEA1, NEA2, NEA3, NEA4, NEA5, and NEA6 disposed in the first direction DR1 and the second direction DR2. The detailed description thereof will be made below with reference to FIG. 10.

Since the remaining parts have been described above in FIG. 5, the detailed descriptions thereof will be omitted below.

FIG. 10 is a cross-sectional view along line C-C’ in FIG. 9.

Referring to FIG. 10, the thin film transistor 130 may be disposed between the buffer layer 120 and the first insulating layer 140. The thin film transistor 130 may be provided as a plurality of thin film transistors and disposed in the non-light-emitting areas NEA1 and NEA4 of the sub-pixels PX1 and PX4.

The source electrode 131 of the thin film transistor 130 disposed in the first non-light-emitting area NEA1 may be electrically connected to the first anode electrode AND1, and the source electrode 131 of the thin film transistor 130 disposed in the fourth non-light-emitting area NEA4 may be electrically connected to the fourth anode electrode AND4.

The second high voltage line DVL_2_1 may be disposed between the first insulating layer 140 and the second insulating layer 150. The second high voltage line DVL_2_1 may be disposed across a boundary between the first non-light-emitting area NEA1 of the first sub-pixel PX1 and the fourth non-light-emitting area NEA4 of the fourth sub-pixel PX4. Accordingly, the first sub-pixel PX1 and the fourth sub-pixel PX4 may be disposed to share the second high voltage line DVL_2_1. In this manner, the aperture ratio of the display panel may be improved.

The second high voltage line DVL_2_1 may be electrically connected to the drain electrode 134 of the thin film transistor 130 disposed in the first non-light-emitting area NEA1 and may also be electrically connected to the drain electrode 134 of the thin film transistor 130 disposed in the fourth non-light-emitting area NEA4. That is, the drain electrode 134 of the thin film transistor 130 disposed in the first non-light-emitting area NEA1 and the drain electrode 134 of the thin film transistor 130 disposed in the fourth non-light-emitting area NEA4 may be electrically connected through the second high voltage line DVL_2_1.

The first scan line SL1 and the second scan line SL2 may be disposed between the second insulating layer 150 and the third insulating layer 160, and the scan lines SL1 and SL2 may be disposed in the non-light-emitting areas NEA1 and NEA4 of the sub-pixels PX1 and PX4, respectively. The scan lines SL1 and SL2 and the second high voltage line DVL_2_1 may be disposed not to overlap each other in the third direction DR3. That is, the first scan line SL1 may be disposed between the gate electrode 132 disposed in the first non-light-emitting area NEA1 and the second high voltage line DVL_2_1 in the second direction DR2, and the second scan line SL2 may be disposed between the gate electrode 132 disposed in the fourth non-light-emitting area NEA4 and the second high voltage line DVL_2_1 in the second direction DR2. The scan lines SL1 and SL2 do not overlap the second high voltage line DVL_2_1 in the third direction DR3, thereby preventing signal interference between the lines.

Since the remaining parts have been described above in FIGS. 6 and 7, the detailed descriptions thereof will be omitted below.

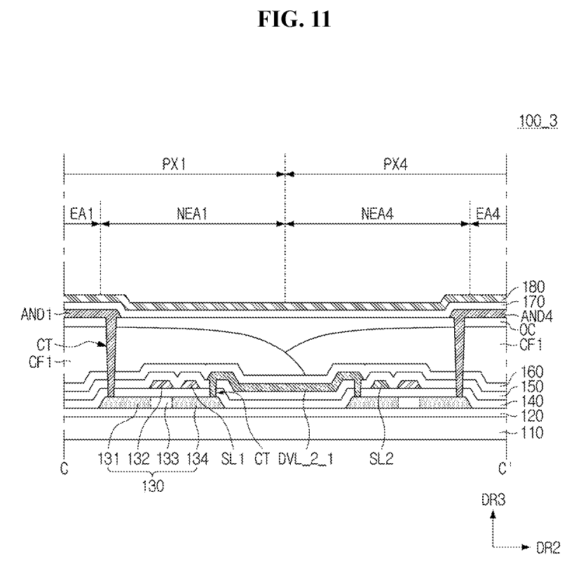

FIG. 11 is a cross-sectional view along line C-C’ in FIG. 9 of the display panel 100_3 according to another embodiment.

Referring to FIG. 11, the scan lines SL1 and SL2 may be disposed between the first insulating layer 140 and the second insulating layer 150, and the second high voltage line DVL_2_1 may be disposed between the second insulating layer 150 and the third insulating layer 160.

In order to prevent signal interference between the scan lines SL1 and SL2 and the second high voltage line DVL_2_1, since the lines should not overlap each other in the third direction DR3, the first scan line SL1 may be disposed between the gate electrode 132 and the second high voltage line DVL_2_1 that are disposed in the first non-light-emitting area NEA1 in the second direction DR2, and the second scan line SL2 may be disposed between the gate electrode 132 and the second high voltage line DVL_2_1 that are disposed in the fourth non-light-emitting area NEA4 in the second direction DR2.

Since the remaining parts have been described above in FIGS. 8 and 10, the detailed descriptions thereof will be omitted below.

In the display device according to the embodiments of the invention, the aperture ratio can be improved by changing the arrangement of the high-voltage lines so that the plurality of pixels share the high-voltage lines.

In the display device according to the embodiments of the invention, the ease of wiring design can be improved by additionally arranging the conductive layer.

In the display device according to the embodiments of the invention, low power can be implemented by improving the aperture ratio of the display device to reduce power consumption.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device comprising:
a substrate including a display area including a plurality of pixels, and a non-display area surrounding the display area;
a first high voltage line surrounding the display area in the non-display area on the substrate; and
a second high voltage line having both ends electrically connected to the first high voltage line and which is electrically connected to a first pixel row including the pixels disposed along a first direction,
wherein the both ends of the second high voltage line are electrically connected to the first high voltage line in the non-display area.

2. The display device of claim 1, further comprising:
a scan line electrically connected to the first pixel row; and
a data line electrically connected to a first pixel column including pixels disposed along a second direction intersecting the first direction,
wherein the second high voltage line, the scan line, and the data line are disposed in different layers.

3. The display device of claim 2, further comprising:
a first conductive layer disposed on the substrate;
a second conductive layer disposed on the first conductive layer; and
a third conductive layer disposed on the second conductive layer.

4. The display device of claim 3, wherein:
the data line is disposed in the first conductive layer;
the second high voltage line is disposed in the third conductive layer; and
the scan line is disposed in the second conductive layer.

5. The display device of claim 3, wherein:
the data line is disposed in the first conductive layer;
the second high voltage line is disposed in the second conductive layer; and
the scan line is disposed in the third conductive layer.

6. The display device of claim 3, further comprising a color filter disposed on the third conductive layer, and a planarization layer disposed on the color filter.

7. The display device of claim 6, wherein:
the pixel includes a plurality of sub-pixels; and
color filters disposed on adjacent sub-pixels overlap each other at boundaries between the adjacent sub-pixels.

8. The display device of claim 3, further comprising an anode electrode,
wherein the anode electrode is disposed on the third conductive layer.

9. The display device of claim 8, wherein:
the pixel includes a light-emitting area and a non-light-emitting area surrounding the light-emitting area;
the anode electrode overlaps the entire light-emitting area; and
a portion of the anode electrode overlaps the non-light-emitting area.

10. The display device of claim 9, wherein the anode electrode and the second high voltage line are electrically connected.

11. The display device of claim 9, wherein the anode electrode and the second high voltage line are electrically connected in the non-light-emitting area.

12. The display device of claim 2, further comprising a second pixel row adjacent to the first pixel row, the first pixel row and the second pixel row being parallel to each other and extending along the first direction,
wherein the second high voltage line is disposed between the first pixel row and the second pixel row.

13. The display device of claim 12, wherein the first pixel row and the second pixel row are electrically connected to the second high voltage line disposed between the first pixel row and the second pixel row.

14. The display device of claim 12, further comprising a plurality of pixel rows parallel to the first pixel row, and a plurality of second high voltage lines,
wherein the arrangement of the pixel rows and the second high voltage lines is repeated along the second direction.

15. A display device comprising:
a substrate including a display area including a first pixel row including a plurality of pixels disposed along a first direction, and a non-display area surrounding the display area;
a first conductive layer;
a buffer layer disposed on the first conductive layer;
a semiconductor layer disposed on the buffer layer;
a first insulating layer disposed on the semiconductor layer;
a second conductive layer disposed on the first insulating layer;
a second insulating layer disposed on the second conductive layer;
a third conductive layer disposed on the second insulating layer; and
a high voltage line electrically connected to the first pixel row and extending in the first direction,
wherein:
the high voltage line is disposed in the first conductive layer, the second conductive layer, or the third conductive layer; and
the high voltage line extends to the non-display area.

16. The display device of claim 15, further comprising:
a scan line electrically connected to the first pixel row; and
a data line electrically connected to a first pixel column including pixels disposed along a second direction intersecting the first direction,
wherein the high voltage line is disposed in the third conductive layer, the scan line is disposed in the second conductive layer, and the data line is disposed in the first conductive layer.

17. The display device of claim 15, further comprising:
a scan line electrically connected to the first pixel row; and
a data line electrically connected to a first pixel column including pixels disposed along a second direction intersecting the first direction,
wherein the high voltage line is disposed in the second conductive layer, the scan line is disposed in the third conductive layer, and the data line is disposed in the first conductive layer.

18. The display device of claim 15, further comprising:
a color filter disposed on the third conductive layer; and
a planarization layer disposed on the color filter,
wherein respective color filters disposed in the plurality of pixels overlap each other at boundaries between the adjacent pixels.

19. The display device of claim 15, further comprising an anode electrode disposed on the third conductive layer,
wherein:
the display area includes a light-emitting area and a non-light-emitting area surrounding the light-emitting area; and
the anode electrode and the high voltage line are electrically connected in the non-light-emitting area.

20. The display device of claim 15, further comprising a second pixel row that is parallel to the first pixel row,
wherein:
the high voltage line is disposed between the first pixel row and the second pixel row; and
the first pixel row and the second pixel row are electrically connected to the high voltage line.

21. A display device comprising:
a display panel including a display area including a plurality of pixels, and a non-display area surrounding the display area;
a shorting bar arranged at one side of the display panel and extending along a first direction in the non-display area;
a first high voltage line surrounding the display area in the non-display area and electrically connected to the shorting bar; and
a second high voltage line extending across the display area and having both ends electrically connected to the first high voltage line, the second high voltage line being electrically connected to a first pixel row including the pixels disposed along the first direction,
wherein the both ends of the second high voltage line are electrically connected to the first high voltage line in the non-display area.

22. The display device of claim 21, further comprising a second pixel row spaced apart from the first pixel row in a second direction crossing the first direction,
wherein the second high voltage line extends between the first pixel row and the second pixel row and is electrically connected to subpixels disposed in each of the first and second pixel rows.

23. The display device of claim 22, further comprising a first signal line and a second signal line electrically connected to the first pixel row and the second pixel row, respectively,
wherein: the first and second signal lines are disposed between the first pixel row and the second pixel row; and
the second high voltage line is disposed between the first and second signal lines.
